(19) United States
(12) Patent Application Publication
(10) Pub. No.: US 2023/0361169 A1
(43) Pub. Date: Nov. 9, 2023

(54) METHOD FOR STABILIZING BREAKDOWN VOLTAGES OF FLOATING GUARD RING

(71) Applicant: National Yang Ming Chiao Tung University, Hsinchu City (TW)

(72) Inventors: Bing-Yue Tsui, Hsinchu City (TW); Yu-Chia Tsui, Zhubei City (TW); Jui-Cheng Wang, Hsinchu City (TW)

(73) Assignee: National Yang Ming Chiao Tung University, Hsinchu City (TW)

(21) Appl. No.: 17/878,208

(22) Filed: Aug. 1, 2022

(30) Foreign Application Priority Data
May 6, 2022 (TW) 111117125

(51) Int. Cl. H01L 29/06; H01L 29/78; H01L 29/16; H01L 21/04

(52) U.S. Cl. CPC H01L 29/0619; H01L 21/0465; H01L 29/1608; H01L 29/7811

(57) ABSTRACT

A method for stabilizing breakdown voltages of floating guard ring, applicable to a high power device, is provided. The high power device has a semiconductor substrate layer, and at least one floating guard ring is formed at its termination. The method includes sequentially providing a pad oxide layer and barrier layer on an upper surface of the high power device to expose the floating guard ring, and then performing an ion implantation step. After removing the pad oxide layer and barrier layer, grow a field oxide layer, such that a defect layer is formed underneath. By employing the formed defect layer, the present invention achieves to control an interface potential level between the field oxide layer and the semiconductor substrate layer fixed at a certain potential value, without being affected by charges in the oxide layer or metal across over it, thereby stabilizing breakdown voltages of floating guard ring.

This application claims priority of Application No. 111117125 filed in Taiwan on 6 May 2022 under 35 U.S.C. § 119; the entire contents of all of which are hereby incorporated by reference.

### BACKGROUND OF THE INVENTION

### Field of the Invention

The present invention is related to a method for stabilizing breakdown voltages of floating guard ring. More particularly, it is related to a process method which is aimed to form a defect layer by growing a field oxide layer subsequently after performing a pre-ion implantation step, so as to stabilize breakdown voltages of the floating guard ring.

### Description of the Prior Art

In general, high power devices have been widely used in various power electronics fields, including: switching elements, motor control, consumer electronics, uninterruptible power systems and so on, due to features of low power consumption, high voltage endurance, rapid switching speed, and safe operating range. Since the applications of power integrated circuits and components in the electrical and related electronic fields are gradually increasing, and the design, manufacture and working conditions of the high power devices are distinct from those of general low power devices, when considering design processes of high power devices, it is usually necessary to give priority to the voltage and current range that the device can withstand, as well as power, usage durability, and reliability, etc. of the device.

Normally, the voltage endurance of high power devices is critical, especially when its interior electric field becomes extremely large and the high electric field is generated at its device boundary. Therefore, for an optimization design condition, it is necessary to ensure that the device is able to withstand high voltages, and as far as possible to control its breakdown voltage to be consistent with properties of the device material itself. Please refer to FIG. 1, which shows a schematic diagram of designing floating guard rings for forming a termination protection structure in the prior art. In such a conventional methodology, the large electric field at the edge of the device can be mainly reduced by extension of its depletion region. Therefore, the configuration of at least one floating guard ring 11 (generally the first one floating guard ring 11 which is the closest one to the PN junction 10) must be designed within the depletion region of the PN junction 10 of the device’s main operating area. In addition, it is also known that parameters such as numbers, spacing, and width of these floating guard rings 11 also need to be carefully designed for achieving optimization of breakdown voltages of the device. Thereby, it affects the process complexity as well. In general, the common process steps of forming the floating guard rings include using lithography to define the pattern first and perform an ion implantation process afterwards. Technically, the ion implantation dose, ion implantation depth, and pattern mask configurations for forming the floating guard rings must be controlled extremely precisely to be effective.

However, in a current floating guard ring device structure, a surface potential of the device is very likely to be affected by charges in the field oxide layer or metal across over it, thereby degrading breakdown voltages of the device. Please refer to FIG. 2 for the data showing that how many percentages of changes in breakdown voltages is related to the charges in the field oxide layer (Qss). From the data as illustrated in FIG. 2, it is obvious that when there are charges existing in the field oxide layer, up to 40% of decrease in changes of the breakdown voltage may be induced.

And for solving these problems, in view of the currently existing technologies regarding the floating guard ring processes, improvements and design modifications of the guard ring itself are commonly taken into considerations, for example, additionally designing an extra region for surface charge compensation, such that the floating guard rings can be less affected by the aforementioned charges. However, it also should be noticed that, by adopting such method, extra process steps are required, and the process complexity is thus increased accordingly. Moreover, the additionally designed region for surface charge compensation also increases the area consumption of the device. It, in contrast, adds the process costs, and as a result, until now still fails to be applied into actual mass production so far.

Therefore, on account of above, to overcome the abovementioned issues, it should be apparent that there is indeed an urgent need for the professionals in the field for a new and novel process method to be developed, that can effectively stabilize breakdown voltages of floating guard rings, and thus solve those above mentioned problems occurring in the prior design. The detailed specific descriptions and implementations will be provided by Applicants of the present invention in the following paragraphs as below.

### SUMMARY OF THE INVENTION

In order to overcome the above-mentioned disadvantages, one major objective in accordance with the present invention is provided for a novel process technology, which is applicable to stabilizing breakdown voltages of floating guard rings. By employing the disclosed process techniques of the present invention, a pre-ion implantation step is performed first. After a thermal oxidation process or chemical vapor deposition process is used to grow a field oxide layer, a defect layer can be formed down below the field oxide layer. When a silicon carbide (SiC) substrate is being applied to, such defect layer will be formed at the SiC surface underneath the field oxide layer. And the defect layer helps to fix the SiC surface potential effectively, for avoiding influences from the charges in the field oxide layer or metal across over it. On account of the technical features of the present invention, it is effective to stabilize breakdown voltages of the floating guard rings and control the voltage endurance of the device in a much more superior manner.

According to the proposed process techniques of the present invention, the ions used in the pre-ion implantation step, including the ion species, implantation energies, implantation dosages, as well as parameters such as temperature and time for performing the thermal oxidation process, are allowed to be adjustable. Therefore, it is believed that the present invention is characterized by great process flexibility.

In addition, according to the disclosed method for stabilizing breakdown voltages of floating guard ring, its application field is not limited to the aforementioned silicon carbide substrates. Based on the same principles, the disclosed method may also be applied to substrates made of other semiconductor materials having wide bandgaps, such as gallium oxide (Ga₂O₃), aluminum nitride (AlN), and diamond, etc. Furthermore, according to the disclosed method for stabilizing breakdown voltages of floating guard ring, it can be applied to high power devices, including: a Schottky Barrier Diode (SBD), a P-i-N diode, a Vertical Double Diffused Metal Oxide Semiconductor Field Effect Transistor (VDMOSFET), and an Insulated Gate Bipolar Transistor (IGBT). To sum up, for those who are skilled in the art and having ordinary knowledge, appropriate modifications or changes based on the technical solutions disclosed in the present invention without departing from the spirit of the present invention are practicable. However, the modifications should still fall into the scope of the present invention. The present invention is certainly not limited thereto the disclosed parameters, conditions, as well as fields of the application.

Based on the novel process techniques provided by Applicants of the present invention, it is aimed to disclose a process method for stabilizing breakdown voltages of floating guard ring. The disclosed breakdown voltages stabilizing process method is applicable to a high power device having a semiconductor substrate layer which is made of a wide bandgap semiconductor material. And, at least one floating guard ring is formed at a termination of the high power device.

According to the breakdown voltages stabilizing process method disclosed in the present invention, it comprises a plurality of following steps:

(a): forming a hard mask on an upper surface of the high power device. The hard mask covers an active region of the high power device without covering the termination where the at least one floating guard ring is formed so as to expose the at least one floating guard ring. According to the various embodiments of the present invention, the hard mask may be a single-layer structure or a stacked structure composed of multiple layers. For instance, the hard mask may comprise a barrier layer, which is made of silicon nitride (Si₃N₄), silicon dioxide (SiO₂) or a material that can be selectively removed from the semiconductor substrate layer (i.e. the wide bandgap semiconductor material). Alternatively, the hard mask may further comprise a pad oxide layer which is configured between the barrier layer and the upper surface of the high power device. The pad oxide layer, for example, can be made of silicon dioxide (SiO₂), and the barrier layer can be further made of another material that can be selectively removed from the pad oxide layer.

(b): performing an ion implantation step, which encompasses at least the termination where the at least one floating guard ring is formed. According to the embodiment of the present invention, such an ion implantation step can be performed by using ions such as argon (Ar), xenon (Xe), phosphorus (P), aluminum (Al), silicon (Si), or oxygen (O). An ion implantation dose of the ion implantation step can be between 10¹² cm⁻² and 10¹⁶ cm⁻². And, an ion implantation energy of the ion implantation step can be between 10 keV and 1000 keV.

(c): removing the hard mask and growing a field oxide layer, such that a defect layer is formed underneath the field oxide layer.

Preferably, it is feasible to grow the field oxide layer before removing the hard mask. And yet, the present invention is certainly not limited to such performing orders.

(d): by employing the defect layer, a surface potential of the semiconductor substrate layer underneath the field oxide layer is fixed at a certain level.

According to the technical contents of the present invention, a thickness of the formed defect layer is between 50 and 500 nm. And a defect density of the defect layer is between 10¹³ cm⁻³ and 10¹⁶ cm⁻³.

In one embodiment of the present invention, the above mentioned field oxide layer can be formed by a chemical vapor deposition process. And yet, in another embodiment of the present invention, when the ion implantation step is performed by using a pre-amorphization implant (PAI) process such that the semiconductor substrate layer is further turned into an amorphous state, under such a circumstance, the field oxide layer is formed by using a thermal oxidation process. In such an embodiment, a process temperature of the thermal oxidation process can be set for example, between 1000 and 1300 Celsius degrees. And a process time of the thermal oxidation process is between 1 and 24 hours. In general, various modifications and variations to the present invention can be made by people who are skilled in the art, without departing from the scope or spirits of the invention. And yet, the present invention covers these modifications and/or variations provided that, they fall within the scope of the invention and its equivalent. The present invention is certainly not limited to the disclosed parameters and conditions as illustrated above. The present invention is characterized by having great process flexibilities.

Based on the above, after the defect layer is successfully formed in the present invention, a plurality of post end processes can be further performed, including:

(e): forming a gate oxide layer on the active region of the high power device.

(f): forming a gate conductive layer on the gate oxide layer. In specific, according to one embodiment of the present invention, regarding forming the gate conductive layer, it is feasible to use a low-pressure chemical vapor deposition (LPCVD) process to deposit polysilicon as a gate material first. After that, an etch back process is employed to etch back the polysilicon, such that the gate conductive layer is formed. And after that, a dielectric layer can be further deposited on the gate conductive layer.

(g): forming at least one contact window which extends through the dielectric layer and the gate oxide layer, and electrically connected to the semiconductor substrate layer of the high power device for providing electrical paths.

According to the present invention, a material of the semiconductor substrate layer, preferably can be an N-type silicon carbide (SiC) substrate.

Therefore, to sum up, it is apparent that the present invention discloses a process method for stabilizing breakdown voltages of floating guard ring. In view of the disclosed process method, it mainly provides an ion implantation step which covers a termination where the floating guard ring is configured. After the ion implantation step is performed, grow a field oxide layer. Since a damaged layer caused by the aforementioned ion implantation is formed underneath the field oxide layer, and such damaged layer cannot be fully healed by the high temperature when growing the field oxide layer, the defect layer described in the present invention is accordingly formed underneath the field oxide layer. By such design manners, an interface potential level between the field oxide layer and its lower semiconductor substrate layer (SiC) can be fixed at a certain potential value due to the formed defect layer. As a result, charges in the field oxide layer or voltages from an upper metal layer will not affect the breakdown voltages, so that breakdown voltages of the floating guard rings are maintained stable and with an excellent voltage endurance capability.

It should be noted that the embodiments disclosed in the present invention are described by illustrating silicon carbide as an exemplary example. It is merely intended to enable those skilled in the art to fully understand the technical solution of the present invention, but not to limit the scope and/or application of the present invention. In other words, according to the process method disclosed hereby the present invention, it is applicable to more than a silicon carbide substrate, but also to a variety of substrates made of various semiconductor materials.

Below, the embodiments are described in detail in cooperation with the drawings, so that these and other objectives of the present invention will become obvious to those of ordinary skill in the art after reading the following detailed description of preferred embodiments. And technical contents, characteristics and accomplishments of the invention are easily comprehensive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic diagram of designing floating guard rings for forming a termination protection structure in the prior art.

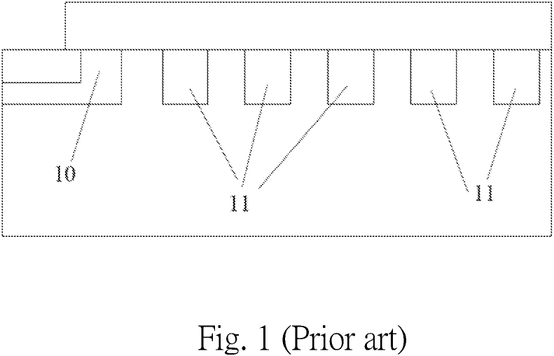

FIG. 2 shows a data diagram illustrating how many percentages of changes in breakdown voltages is related to the charges in the field oxide layer (Qss).

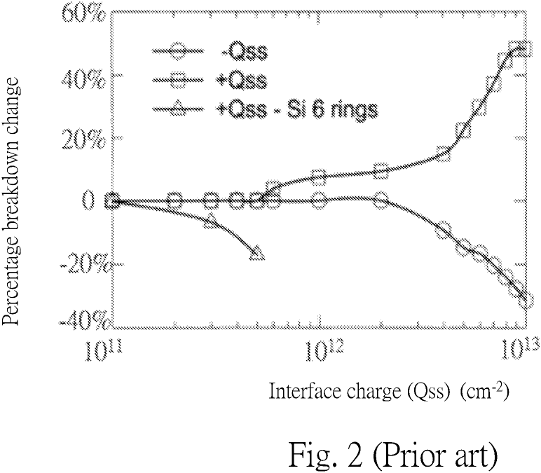

FIG. 3A shows a schematic structural diagram of forming an N-type epitaxial layer on an N-type semiconductor substrate in accordance with one embodiment of the present invention.

FIG. 3B shows a schematic structural diagram from FIG. 3A after the source ion implantation, definition and ion implantations of the P-type heavily doped regions and P-type body regions.

FIG. 3C shows a schematic structural diagram from FIG. 3B after at least one floating guard ring is formed at a termination.

FIG. 3D shows a schematic structural diagram from FIG. 3C when a hard mask is provided on the upper surface of the high power device.

FIG. 3E shows a schematic structural diagram from FIG. 3D when an ion implantation step is performed.

FIG. 3F shows a schematic structural diagram from FIG. 3E after a field oxide layer is grown.

FIG. 3G shows a schematic structural diagram in accordance with one embodiment of the present invention wherein the hard mask includes a pad oxide layer and a barrier layer.

FIG. 3H shows a schematic structural diagram from FIG. 3F, in which a gate oxide layer is formed.

FIG. 3I shows a schematic structural diagram from FIG. 3H, in which a gate conductive layer is further formed on the gate oxide layer.

FIG. 3J shows a schematic structural diagram from FIG. 3I, in which a dielectric layer is further deposited and at least one contact window is formed to complete the transistor fabrication.

FIG. 4 shows a process flow chart illustrating the steps of the proposed method for stabilizing breakdown voltages of floating guard ring in accordance with the embodiment of the present invention.

FIG. 5 shows a data diagram of breakdown voltage analysis derived from a conventional VDMOSFET having merely floating guard ring structure.

FIG. 6 shows a data diagram of breakdown voltage analysis derived from a modified VDMOSFET having floating guard ring structure whereby the disclosed stabilizing method of the present invention is applied.

### DESCRIPTION OF THE PREFERRED EMBODIMENTS

It is to be understood that both the foregoing general description and the following detailed description are exemplary and are intended to provide further explanation of the invention as claimed.

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

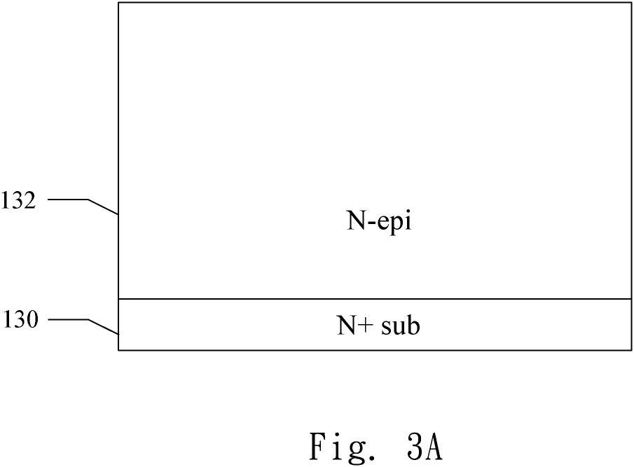

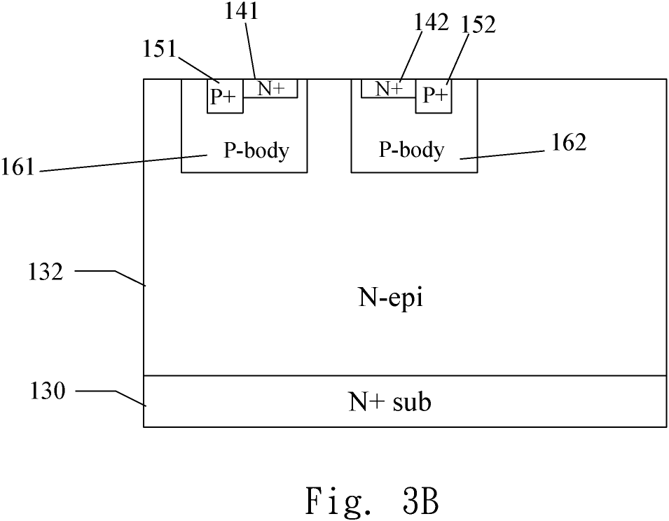

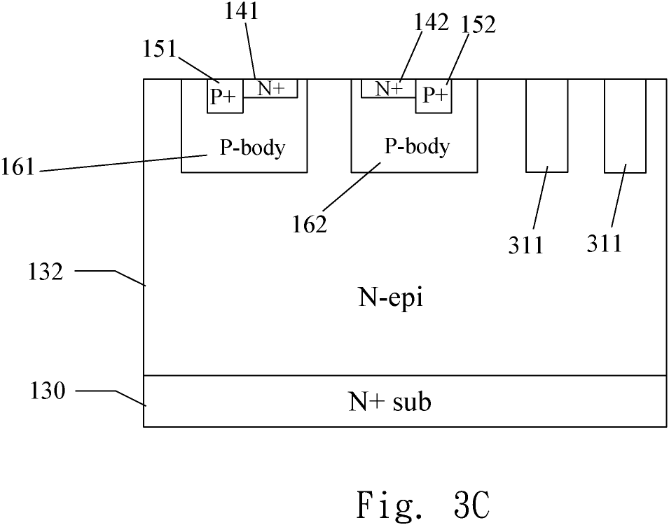

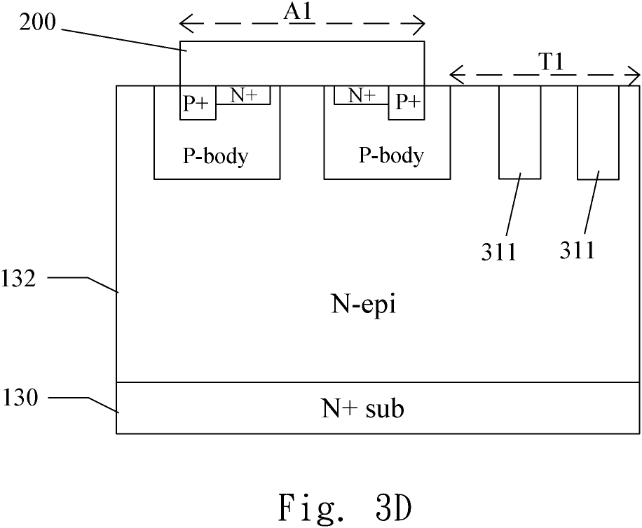

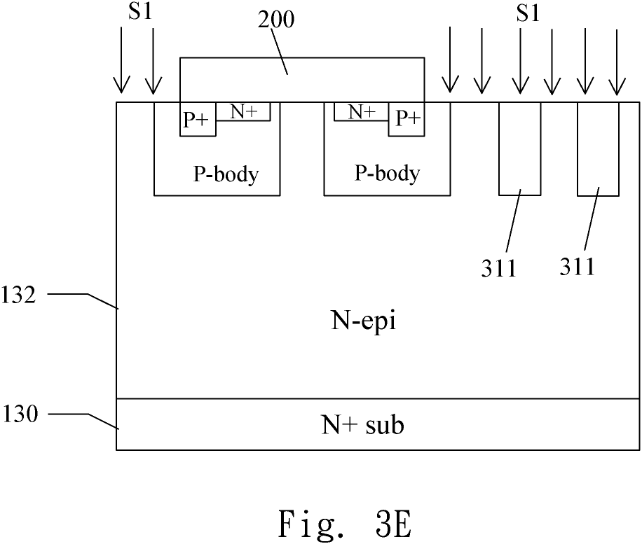

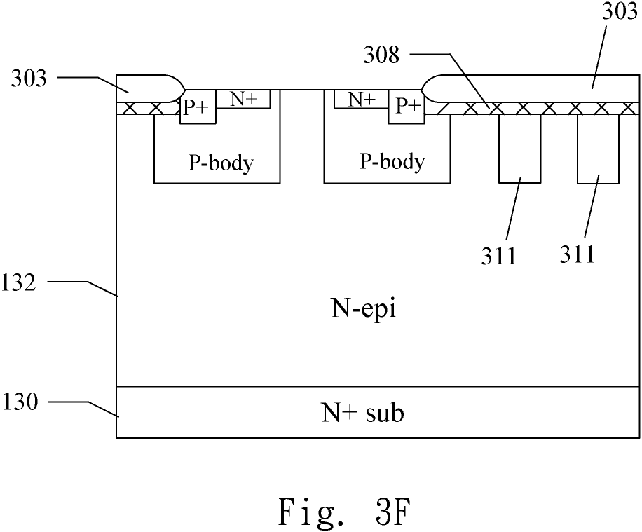

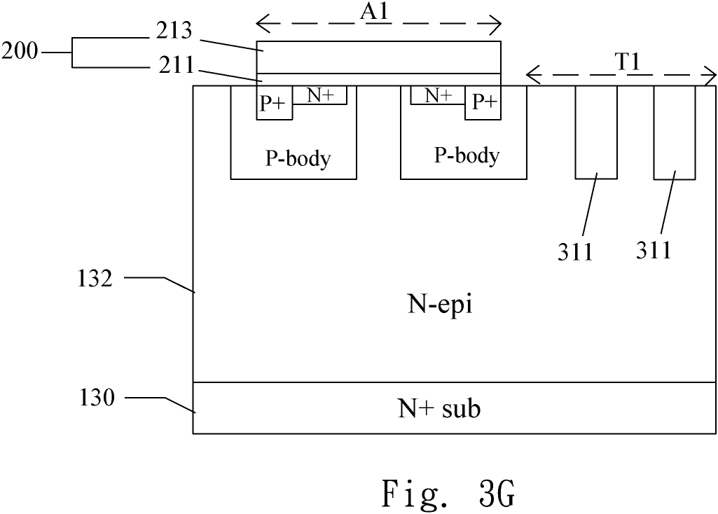

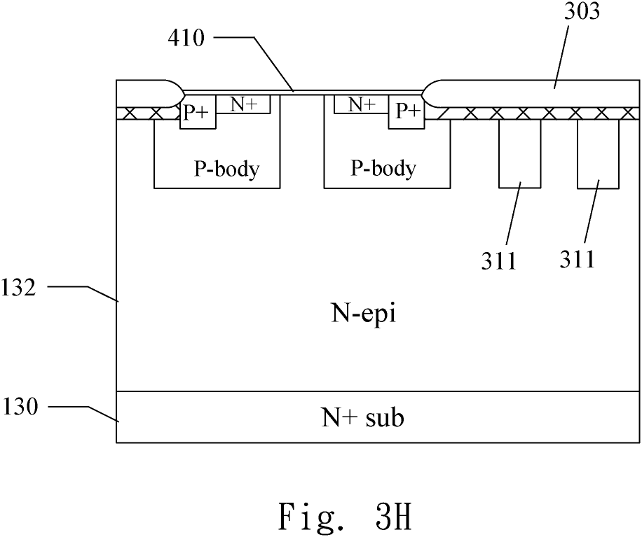

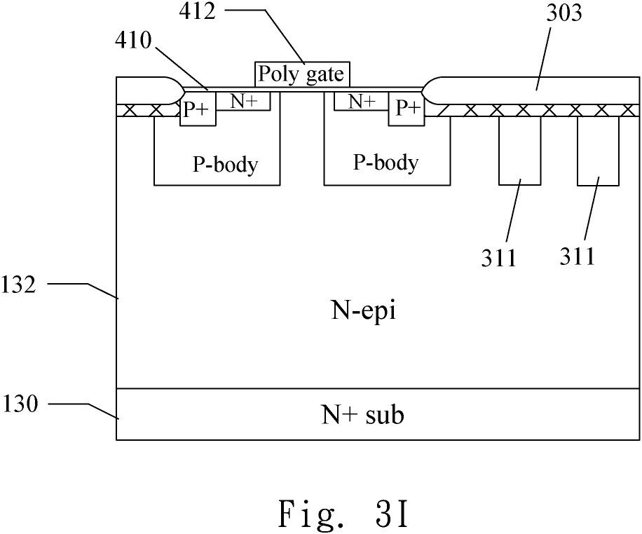

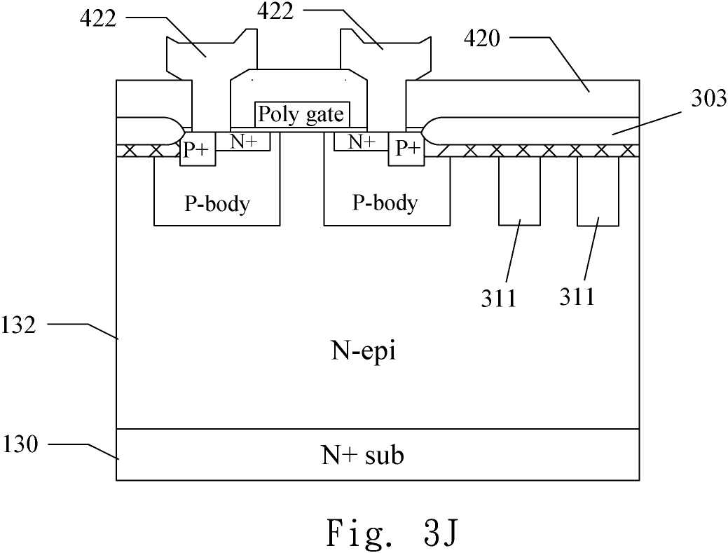

The present invention discloses a method for stabilizing breakdown voltages of floating guard ring. Please refer to FIG. 3A to FIG. 3J, which accompanying show schematic cross-sectional views of the structure of a high power device by employing the proposed method disclosed in the present invention. According to the present invention, the high power device includes a semiconductor substrate layer, which is made of a wide bandgap semiconductor material. First, please refer to FIG. 3A, wherein an N-type semiconductor substrate (shown as N+ sub) 130 is provided, and an N-type epitaxial layer (shown as N-epi) 132 is formed on the N-type semiconductor substrate 130. In such step, according to one preferred embodiment of the present invention, the N-type semiconductor substrate (N+ sub) 130 preferably, is an N-type silicon carbide (SiC) substrate. And, an N-type SiC epitaxial layer with a doping concentration of 1×10¹⁶ cm⁻³ and a thickness of 5.5 µm is grown on the front side of the substrate 130 as the N-type epitaxial layer (N-epi) 132 by epitaxial growth, so as to form the structure as shown in FIG. 3A. Hereinafter, it is worth noting that the substrate material is not limited to silicon carbide. Alternative materials, including the wide bandgap semiconductor materials such as: gallium oxide (Ga₂O₃), aluminum nitride (AlN), and diamond are also feasible for fabrication of the substrate of the present invention. In the following descriptions, the Applicants merely take the substrate made of N-type silicon carbide as an illustrative example for introducing the technical features of the present invention. In the same manners, those skilled in the art are acknowledged to apply the disclosed method in the present invention to the device having a P-type semiconductor substrate on account of teachings from the present invention. Similar descriptions are thus omitted in the present invention.

Next, after RCA cleaning, silicon dioxide is deposited as a hard mask and a lithography process is employed to define an N+ source window. According to the embodiment of the present invention as shown in FIG. 3B, a first N-type heavily doped region (N+) 141 and a second N-type heavily doped region (N+) 142 are formed by using a source ion implantation in the N-type epitaxial layer 132. Subsequently, after the source ion implantation, the hard mask is removed, and the RCA cleaning is performed repeatedly. After, the P-type heavily doped regions and P-type body regions are defined and ion implantations are carried out, so that a first P-type heavily doped region (P+) 151, a second P-type heavily doped region (P+) 152, a first P-type body region (P-body) 161 and a second P-type body region (P-body) 162 are formed as illustrated in FIG. 3B.

In such a structure, the first P-type body region 161 and the second P-type body region 162 are formed in the N-type epitaxial layer 132. The first P-type heavily doped region 151 is disposed on one side of the first N-type heavily doped region 141, and the first P-type heavily doped region 151 and the first N-type heavily doped region 141 are commonly disposed in the first P-type body region 161. The second P-type heavily doped region 152 is disposed on one side of the second N-type heavily doped region 142, and the second P-type heavily doped region 152 and the second N-type heavily doped region 142 are commonly disposed in the second P-type body region 162. Hereinafter, the semiconductor substrate layer of the applied high power device (N-channel VDMOSFET) in the embodiment is formed. However, the high power devices in which the present invention can be applied are not limited to such an N-channel VDMOSFET. Any other P-channel high power devices are also implementable. According to the stabilizing method for breakdown voltages of floating guard ring disclosed in the present invention, the method is not limited by being applied to transistors. Overall, it is well known that any kind of high power devices has termination protection structure requirements. And, among them, floating guard rings are the most commonly used. Therefore, it is believed that the proposed stabilizing method for breakdown voltages of floating guard ring disclosed in the present invention can be widely used in any high power device having floating guard rings as its termination protection structure. In this embodiment of the present invention, an N-channel VDMOSFET is simply taken as an explanatory one for describing the technical contents of the invention, and yet is not intended to limit the scope of the present invention.

And then, silicon dioxide is used again as a hard mask and a lithography process is employed to define the floating guard ring window for floating guard ring ion implantation. Later on, the hard mask is removed, such that at least one floating guard ring 311 is formed at a termination of the high power device. The structure as shown in FIG. 3C is thus provided. The above mentioned process flows are the standard processes of forming a VDMOSFET. In the following, the innovative process flows of the present invention will be described in details for references.

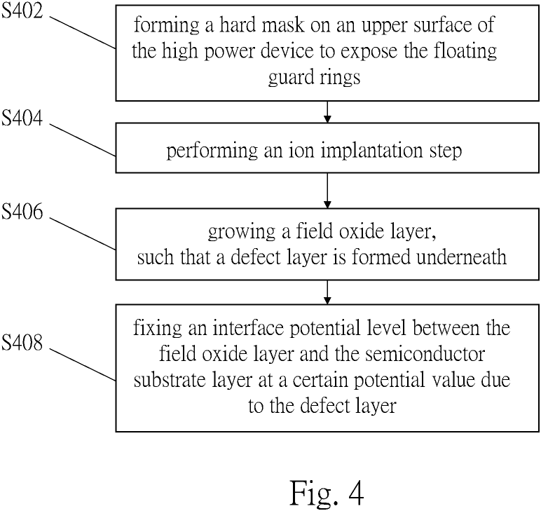

Please further refer to FIG. 4 at the same time. In FIG. 4, the present invention discloses a process flow illustrating the steps of the proposed method for stabilizing breakdown voltages of floating guard ring. The proposed method includes the steps of S402, S404, S406 and S408. As mentioned above, after completing the standard processes of forming the VDMOSFET (as shown in FIG. 3C), the present invention proceeds to perform the step S402 to form a hard mask 200 on an upper surface of the high power device. As shown in FIG. 3D, the hard mask 200 covers an active region A1 of the high power device without covering the termination T1 where the floating guard rings 311 are formed so as to expose the floating guard rings 311. To be specific, according to the embodiment of the present invention, the hard mask 200 may be a single-layer structure or a stacked structure composed of multiple layers. The actual material and structure of the hard mask 200 can be determined according to the semiconductor substrate material of the high power device as well as the subsequent field oxidation process conditions. More detailed descriptions will be provided later as follows.

After forming the hard mask 200 in FIG. 3D, as illustrated in the step S404, the present invention proceeds to perform an ion implantation step, as shown in the implantation direction S1 in FIG. 3E. Since the active region A1 of the VDMOSFET is protected by the hard mask 200 and only the termination T1 where the floating guard rings 311 are disposed is exposed, the ion implantation step performed in the step S404 encompasses at least the termination T1 where the floating guard rings 311 are disposed for ions implantation. According to the embodiment of the present invention, such ion implantation step can be performed by using ions such as argon (Ar), xenon (Xe), phosphorus (P), aluminum (Al), silicon (Si), or oxygen (O). An ion implantation dose of the ion implantation step can be, for example, between 10¹² cm⁻² and 10¹⁶ cm⁻². An ion implantation energy of the ion implantation step can be, for example, between 10 keV and 1000 keV. In one embodiment, for instance, when argon ions are used for ion implantation, the ion implantation dose is 5*10¹⁴ cm⁻². On the contrary, when heavier ions are used instead, then the ion implantation dose and ion implantation energy can be reduced. The present invention is characterized by having superior process flexibility and is certainly not limited to the parameters disclosed herein.

Afterwards, please refer to the step S406, in which the present invention further removes the foregoing hard mask 200 and grows a field oxide layer after the previous ion implantation step is complete. According to one embodiment of the present invention, practically, it is feasible to grow the field oxide layer before removing the hard mask 200. However, it is believed that the present invention is certainly not limited to such performing orders. What is important is to form a defect layer underneath the field oxide layer.

In details, as shown in FIG. 3F, since underneath the formed field oxide layer 303 is a layer damaged by the aforementioned ion implantation (argon ions), however, such SiC layer has not turned into an amorphous state and thus will not grow into silicon dioxide. In addition, these damages cannot be completely healed by the high temperature when growing the field oxide layer. Therefore, a defect layer 308 will be formed underneath the field oxide layer 303 as illustrated in FIG. 3F. After that, as described in the step S408, by employing the defect layer 308, an interface potential level between the field oxide layer 303 and the semiconductor substrate layer of the VDMOSFET (SiC) can be fixed at a certain potential value. And due to a fixed SiC surface potential, which is not affected by charges in the field oxide layer or its upper metal layer (for instance, metal across over the floating guard ring), the present invention achieves an inventive objective of effectively stabilizing breakdown voltages of the floating guard ring.

According to one embodiment of the present invention, a thickness of the formed defect layer 308 is, for example, between 50 and 500 nm. A defect density of the defect layer 308 is between 10¹³ cm⁻³ and 10¹⁶ cm⁻³. Preferably, the defect density is between 10¹⁴ cm⁻³ and 10¹⁵ cm⁻³.

It draws our attention that, according to one embodiment of the present invention, the above mentioned field oxide layer 303 can be formed by using a basic chemical vapor deposition (CVD) process. However, as the ion implantation step disclosed in the step S404 is performed by using a pre-amorphization implant (PAI) process such that the SiC semiconductor substrate layer is further turned into an amorphous state (amorphous Si), under such circumstances, then the field oxide layer 303 is formed by using a thermal oxidation process.

In such an embodiment, a process temperature of the thermal oxidation process can be determined, for example, between 1000 and 1300 Celsius degrees. And a process time of the thermal oxidation process is between 1 and 24 hours. For instance, when the process temperature of the thermal oxidation process is 1100 Celsius degrees, a process time of the thermal oxidation process is about 5 hours. However, when the process temperature of the thermal oxidation process is 1050 Celsius degrees, then the process time of the thermal oxidation process is increased to 11 hours.

In general, according to the processes for ion implantation, field oxide layer growth, as well as various conditions for performing the processes, such as process temperature, process time, and so on, it is ensured that certain process flexibility is allowed and practical. It is worth emphasizing that, the present invention is definitely not limited to the above-mentioned thickness, dimensions or process parameters, including process temperature, process time, and ion species used for ion implantation, etc. which were disclosed in the previously described embodiments. For people who are skilled in the art and with ordinary knowledge in the field, modifications without departing from the spirit of the present invention are permitted. However, within the scope of its equality, it is believed that such modifications should still fall into the scope and claims of the present invention.

And furthermore, according to the previously described technical contents regarding design for the hard mask 200, the Applicants of the present invention provide several various embodiments as follows for further references. In one embodiment, when the above mentioned field oxide layer 303 is formed by using a thermal oxidation process and the substrate is a SiC substrate, then the hard mask 200 preferably may comprise a pad oxide layer 211 and a barrier layer 213 as shown in FIG. 3G of the present invention. In such an embodiment, the pad oxide layer 211 can be made of silicon dioxide (SiO₂), and by deposition of silicon dioxide forms the pad oxide layer 211. Subsequently, silicon nitride (Si₃N₄) is deposited by chemical vapor deposition process as the material of the barrier layer 213, such that the pad oxide layer 211 is configured between the barrier layer 213 and the upper surface of the high power device. Afterwards, the following field oxidation regions can be further defined by lithography along with etching processes. However, according to other embodiment of the present invention, the pad oxide layer 211 may also be not necessary. Or alternatively, the barrier layer 213 may also be made of a material that can be selectively removed from the pad oxide layer 211 (silicon dioxide, for instance).

And in another aspect, as for when the above mentioned field oxide layer 303 is formed by using a chemical vapor deposition process, then the hard mask 200, under such condition, can be made of a material that can be selectively removed from the SiC substrate and resistant to the ion implantation, for example, silicon dioxide. And yet, in a further embodiment of the present invention when the substrate is not made of silicon carbide, and the field oxide layer 303 can only be formed by using a chemical vapor deposition process but not a thermal oxidation process, in such an embodiment, then the hard mask 200 can be made of a material that can be selectively removed from the semiconductor substrate (i.e. the wide bandgap semiconductor material) and resistant to the ion implantation. Silicon dioxide, for instance, can be taken as the material for forming the hard mask 200 under such a circumstance. Overall, the main technical solution of the present invention is to provide a hard mask 200 that can cover an active region A1 of the high power device and expose the termination T1 where the floating guard rings 311 are located, such that the defect layer 308 can be accordingly formed by adopting the aforementioned ion implantation step. As for the structure of the applied hard mask 200, it may be a single-layer structure (including only the barrier layer 213) or a stacked structure composed of multiple layers (including the barrier layer 213 and the pad oxide layer 211). The present invention is advantageous of having extraordinary process flexibility, and not limited by such criteria.

Next, please proceed for referring to FIG. 3H, in which a gate oxide layer 410 on the active region of the VDMOSFET is formed by employing either a thermal oxidation process or a chemical vapor deposition process. A gate conductive layer 412 is then formed on the gate oxide layer 410 as shown in FIG. 3I. In one preferrable embodiment of the present invention, a low-pressure chemical vapor deposition (LPCVD) process is usually firstly used to deposit polysilicon as a gate material in the current manufacturing process. After that, an etch back process is employed to etch back the polysilicon, so as to form the structure of the gate conductive layer 412 as shown in FIG. 3I.

And then, as shown in FIG. 3J, a dielectric layer 420 is further deposited on the gate conductive layer 412. Finally, at least one contact window 422 is formed and followed by a plurality of process steps including contact window etching, metal deposition, metal etching, etc., wherein the contact windows 422 extend through the dielectric layer 420 and the gate oxide layer 410, and electrically connected to the semiconductor substrate layer of the high power device for providing electrical paths. On the other hand, from another perspective view (not seen in this figure), the polysilicon gate will also need to have alleged metal contacts. Nevertheless, since the configurations are not seen from the cross section of this perspective view in such figure, and those skilled in the art should be able to implement based on various requirements, redundant descriptions are disregarded herein.

General speaking, considering the post end process steps from FIG. 3H to FIG. 3J including: using a thermal oxidation process or a chemical vapor deposition process to form the gate oxide layer 410 (FIG. 3H), performing gate deposition (FIG. 3I), performing dielectric layer deposition, contact window etching, metal deposition, and metal etching (FIG. 3J), since these steps are mostly the same as they are in a conventional VDMOSFET manufacturing process and the fabrication device is shown in FIG. 3J, the present invention is thus not intended to go deeper into details regarding the post end process flows.

What is important lies in, the inventive spirit of the present invention focuses on how to form the disclosed defect layer on the surface of the semiconductor substrate layer (SiC) in a high power device. And due to the effect of the defect layer, which fixes the SiC surface potential at a certain potential value without being affected by its upper metal layer or charges in the oxide layers, breakdown voltages of the floating guard rings are therefore successfully stabilized. As a result, it is also believed that in view of the proposed breakdown voltages stabilizing method disclosed by the present invention, it is effective in improving reliability of the voltage endurance capability of the floating guard ring, such that its breakdown voltage can be less interfered by metal wiring. Among these points of views, the present invention is undoubtedly innovative and practical.

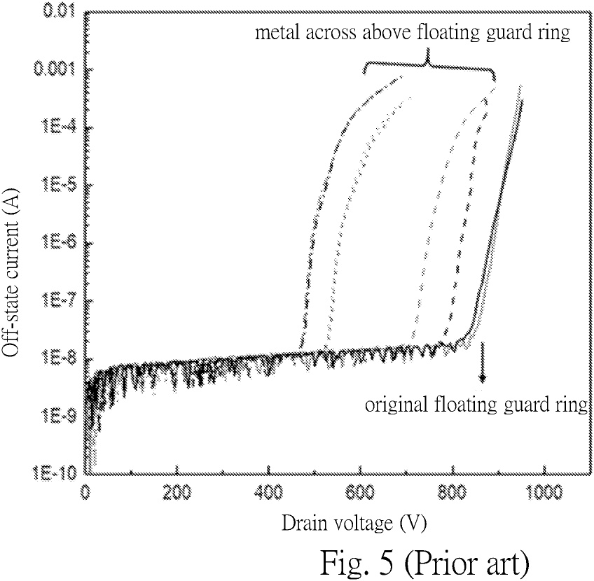

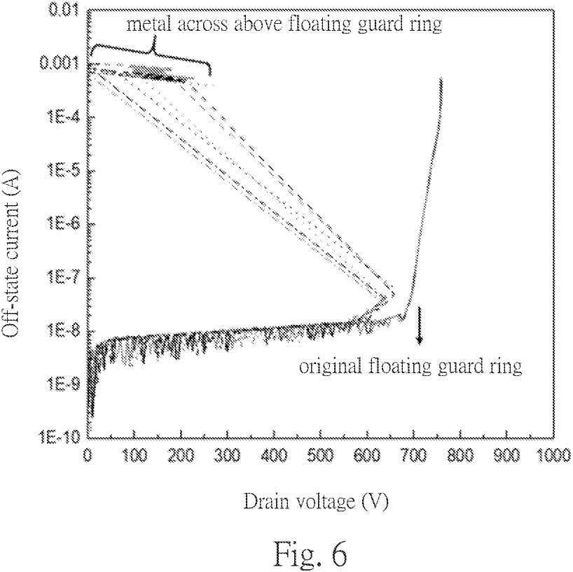

In the following descriptions, please further refer to FIG. 5 and FIG. 6 for data diagrams of breakdown voltage analyses. The two data diagrams are respectively derived from a conventional VDMOSFET having merely floating guard ring structure and from a modified VDMOSFET having floating guard ring structure whereby the disclosed stabilizing method of the present invention is applied. As can be seen from FIG. 5, when there is metal across above floating guard ring structure of the VDMOSFET, the device’s breakdown voltage is affected and drops extremely significantly. On the contrary, as can be seen in FIG. 6, when the proposed defect layer is formed underneath the field oxide layer due to a pre-amorphization implant (PAI) process as the present invention disclosed, so that a surface potential level of the device is fixed, the device’s breakdown voltage is nearly unaffected, and the change in breakdown voltages is almost extremely tiny even when there is metal across above its floating guard ring structure. Therefore, from these two comparative data diagrams, it is obvious that by employing the process steps disclosed in the present invention as mentioned in the earlier paragraphs, the present invention indeed and effectively improves the breakdown voltage stability of the floating guard ring structure and a well breakdown characteristic of the device is maintained. Compared with the existing technologies, the present invention achieves in outstanding inventive effects.

As a result, to sum up, the present invention is aimed to provide a novel process technique, which comprises using a pre-amorphization implant process before growing a field oxide layer by either a thermal oxidation process or a chemical vapor deposition process. By such process manner, a defect layer can be formed on the surface of the power device and therefore, the surface potential of the power device is able to be fixed and controlled at a certain potential value due to the defect layer. As a result, even though there will be charges in the oxide layer or an upper metal layer forms across over the device, the breakdown voltages of the device will not be affected and keeps stabilized. As compared with the current technologies, it is believed that the present invention and process methods being proposed are able to effectively solve the issues existing in the prior arts. In addition, the proposed process method of the present invention can be applied to not only silicon carbide substrate, but also various substrates which are made of wide bandgap materials. Also, the disclosed process method of the present invention can be applicable to not only a general VDMOSFET structure, but also any other semiconductor device having the VDMOSFET structure, for example, an IGBT. In view of all, the Applicants assert that the present invention is instinct, effective and highly competitive for incoming technologies, industries and researches developed in the future. And since the technical features, means and effects achieved by the present invention are significantly different from the current solutions, and can not be accomplished easily by those who are familiar with the industry, it is thus believed that the present invention is indeed characterized by patentability and shall be patentable soon in a near future.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A method for stabilizing breakdown voltages of floating guard ring, which is applicable to a high power device including a semiconductor substrate layer made of a wide bandgap semiconductor material, and at least one floating guard ring is formed at a termination of the high power device, the method comprising:
forming a hard mask on an upper surface of the high power device, such that the hard mask covers an active region of the high power device without covering the termination where the at least one floating guard ring is formed so as to expose the at least one floating guard ring;
performing an ion implantation step, which encompasses the termination where the at least one floating guard ring is formed;
removing the hard mask and growing a field oxide layer, such that a defect layer is formed underneath the field oxide layer; and
fixing an interface potential level between the field oxide layer and the semiconductor substrate layer at a certain potential value by employing the defect layer.

2. The method according to claim 1, wherein the field oxide layer is formed by a chemical vapor deposition process.

3. The method according to claim 1, wherein when the ion implantation step further turns the semiconductor substrate layer into an amorphous state, the field oxide layer is formed by a thermal oxidation process.

4. The method according to claim 3, wherein a process temperature of the thermal oxidation process is between 1000 and 1300 Celsius degrees.

5. The method according to claim 3, wherein a process time of the thermal oxidation process is between 1 and 24 hours.

6. The method according to claim 3, wherein the ion implantation step is performed by a pre-amorphization implant (PAI) process.

7. The method according to claim 1, wherein the ion implantation step is performed by using ions such as argon (Ar), xenon (Xe), phosphorus (P), aluminum (Al), silicon (Si), or oxygen (O).

8. The method according to claim 1, wherein an ion implantation dose of the ion implantation step is between 10¹² cm⁻² and 10¹⁶ cm⁻².

9. The method according to claim 1, wherein an ion implantation energy of the ion implantation step is between 10 keV and 1000 keV.

10. The method according to claim 1, wherein the wide bandgap semiconductor material comprises silicon carbide (SiC), gallium oxide (Ga₂O₃), aluminum nitride (A1N), and diamond.

11. The method according to claim 1, wherein the high power device is a Vertical Double Diffused Metal Oxide Semiconductor Field Effect Transistor (VDMOSFET), or an Insulated Gate Bipolar Transistor (IGBT).

12. The method according to claim 1, wherein the hard mask comprises a barrier layer, which is made of silicon nitride (Si₃N₄), silicon dioxide (SiO₂) or a material that can be selectively removed from the wide bandgap semiconductor material.

13. The method according to claim 12, wherein the hard mask further comprises a pad oxide layer which is configured between the barrier layer and the upper surface of the high power device, the pad oxide layer is made of silicon dioxide (SiO₂), and the barrier layer is further made of another material that can be selectively removed from the pad oxide layer.

14. The method according to claim 1, wherein a thickness of the defect layer is between 50 and 500 nm.

15. The method according to claim 1, after the defect layer is formed, further comprising:
forming a gate oxide layer on the active region of the high power device;
forming a gate conductive layer on the gate oxide layer and further depositing a dielectric layer on the gate conductive layer; and
forming at least one contact window which extends through the dielectric layer and the gate oxide layer, and electrically connected to the semiconductor substrate layer of the high power device for providing electrical paths.

16. The method according to claim 15, wherein in the step of forming the gate conductive layer, further comprising:
using a low-pressure chemical vapor deposition (LPCVD) process to deposit a polysilicon; and
using an etch back process to etch back the polysilicon, so as to form the gate conductive layer.

17. The method according to claim 1, wherein the semiconductor substrate layer of the high power device comprises an N-type semiconductor substrate, an N-type epitaxial layer, a first N-type heavily doped region, a second N-type heavily doped region, a first P-type heavily doped region, a second P-type heavily doped region, a first P-type body region, and a second P-type body region, the N-type epitaxial layer is disposed on the N-type semiconductor substrate, the first P-type body region and the second P-type body region are formed in the N-type epitaxial layer, the first P-type heavily doped region is disposed on one side of the first N-type heavily doped region, and the first P-type heavily doped region and the first N-type heavily doped region are commonly disposed in the first P-type body region, the second P-type heavily doped region is disposed on one side of the second N-type heavily doped region, and the second P-type heavily doped region and the second N-type heavily doped region are commonly disposed in the second P-type body region.

18. The method according to claim 17, wherein the first N-type heavily doped region and the second N-type heavily doped region are formed by using a source ion implantation in the N-type epitaxial layer.

19. The method according to claim 17, wherein the N-type semiconductor substrate is an N-type silicon carbide (SiC) substrate.

20. The method according to claim 1, wherein a defect density of the defect layer is between 10¹³ cm⁻³ and 10¹⁶ cm⁻³.
